(19) United States
(12) Patent Application Publication
(10) Pub. No.: US 2022/0416512 A1
(43) Pub. Date: Dec. 29, 2022

(54) GALLIUM ARSENIDE BASED MULTI-JUNCTION DILUTE NITRIDE LONG-WAVELENGTH VERTICAL-CAVITY SURFACE-EMITTING LASER

(71) Applicant: Lumentum Operations LLC, San Jose, CA (US)

(72) Inventors: Jun YANG, Cupertino, CA (US); Ajit Vijay BARVE, San Jose, CA (US); Guowei ZHAO, Milpitas, CA (US); Matthew Glenn PETERS, Menlo Park, CA (US); Eric R. HEGBLOM, Sunnyvale, CA (US)

(21) Appl. No.: 17/451,167

(22) Filed: Oct. 18, 2021

Related U.S. Application Data
(60) Provisional application No. 63/202,905, filed on Jun. 29, 2021.

(51) Int. Cl. H01S 5/34; H01S 5/343; H01S 5/183

(52) U.S. Cl. CPC H01S 5/3416; H01S 5/34306; H01S 5/18311

(57) ABSTRACT

A vertical-cavity surface-emitting laser (VCSEL) may include a substrate. The VCSEL may include a bottom mirror structure over the substrate. The VCSEL may include a first dilute nitride active region over the bottom mirror structure. The VCSEL may include a tunnel junction over the first dilute nitride active region. The VCSEL may include a second dilute nitride active region over the tunnel junction. The VCSEL may include a top mirror structure over the second dilute nitride active region.

### CROSS-REFERENCE TO RELATED APPLICATION

This Patent Application claims priority to U.S. Provisional Patent Application No. 63/202,905, filed on Jun. 29, 2021, and entitled “GALLIUM ARSENIDE BASED MULTI-JUNCTION DILUTE NITRIDE LONG-WAVELENGTH VERTICAL-CAVITY SURFACE-EMITTING LASER.” The disclosure of the prior Application is considered part of and is incorporated by reference into this Patent Application.

### TECHNICAL FIELD

The present disclosure relates generally to a vertical-cavity surface-emitting laser (VCSEL) and, more particularly, to a VCSEL comprising multiple active regions including dilute nitride quantum wells, where the multiple active regions are connected in series by one or more tunnel junctions.

### BACKGROUND

A VCSEL is a semiconductor laser, more specifically a diode laser with a monolithic laser resonator, where light is emitted in a direction perpendicular to a chip surface. Typically, the laser resonator consists of two distributed Bragg reflector (DBR) mirrors parallel to a chip surface, between which is an active region (consisting of one or more quantum wells) that generates light. Commonly, the upper and lower mirrors of a VCSEL are doped as p-type and n-type materials, respectively, thereby forming a diode junction.

### SUMMARY

In some implementations, a vertical-cavity surface-emitting laser (VCSEL) includes a substrate; a bottom mirror structure over the substrate; a first dilute nitride active region over the bottom mirror structure; a tunnel junction over the first dilute nitride active region; a second dilute nitride active region over the tunnel junction; and a top mirror structure over the second dilute nitride active region.

In some implementations, a VCSEL includes a substrate; a bottom mirror structure over the substrate; a plurality of dilute nitride active regions over the bottom mirror structure; a set of tunnel junctions over the bottom mirror structure, wherein a tunnel junction of the set of tunnel junctions is between a pair of dilute nitride active regions of the plurality of dilute nitride active regions; and a top mirror structure over the plurality of dilute nitride active regions and the set of tunnel junctions.

In some implementations, an emitter includes a first dilute nitride active region; a second dilute nitride active region; and a tunnel junction between the first dilute nitride active region and the second dilute nitride active region, wherein the first dilute nitride active region and the second dilute nitride active region are connected in series by the tunnel junction.

### BRIEF DESCRIPTION OF THE DRAWINGS

FIGS. 1A and 1B are diagrams illustrating an example of a conventional VCSEL.

FIGS. 2A-2C are diagrams associated with a first example implementation of a VCSEL array including multiple dilute nitride active regions connected in series by one or more tunnel junctions, as described herein.

FIGS. 3A-3C are diagrams associated with a second example implementation of a VCSEL array including multiple dilute nitride active regions connected in series by one or more tunnel junctions, as described herein.

FIG. 4 is a flowchart of an example process relating to manufacturing a VCSEL array including multiple dilute nitride active regions connected in series by one or more tunnel junctions.

### DETAILED DESCRIPTION

The following detailed description of example implementations refers to the accompanying drawings. The same reference numbers in different drawings may identify the same or similar elements.

A dilute nitride material, such as indium gallium arsenide nitride (InGaAsN) or InGaAsN antimony (InGaAsNSb), can be used as a material for an active region of a GaAs-based emitter (e.g., a VCSEL, an edge emitting laser, or the like) to provide a long-wavelength emitter (e.g., an emitter with a lasing wavelength in a range from approximately 1200 nanometers (nm) to approximately 1600 nm).

However, some performance characteristics of a dilute nitride emitter (e.g., an InGaAsN emitter, InGaAsNSb emitter, or the like), such as optical power and wall-plug-efficiency (WPE), are lower than those of a conventional GaAs or indium phosphide (InP) based III-V compound emitter. The reduction in performance is a result of (1) material maturity of the dilute nitride material (e.g., InGaAsN, InGaAsNSb, or the like) being unable to match that of GaAs or InP based III-V compounds (e.g., InGaAs, AlGaAs, GaAsP, or InGaP, and their alloys) and (2) the tendency of the dilute nitride material to suffer poor carrier confinement in quantum wells (e.g., using a conventional InGaAsNSb/GaAsN heterostructure). As one example, for a dilute nitride VCSEL with an InGaAsNSb/GaAsN active region grown on a GaAs substrate lasing at approximately 1380 nm, the WPE is less than approximately 10%. For comparison, a conventional GaAs-based VCSEL can achieve a WPE of greater than approximately 30% (depending on design and operating conditions). In general, embedding the dilute nitride material into a conventional III-V compound emitter structure may not provide sufficient gain to meet a demand on power or WPE for a given application.

Some implementations described herein provide a multi junction VCSEL comprising multiple active regions (e.g., multiple p-i-n active regions) comprising dilute nitride material (e.g., InGaAsN or InGaAsNSb) quantum wells, where the multiple active regions are connected in series by one or more tunnel junctions. In some implementations, the multiple active regions comprising the dilute nitride quantum wells (herein referred to as dilute nitride active regions) are embedded between a first (e.g., top) mirror structure (e.g., a p-type mirror structure, such as a p-type distributed Bragg reflector (p-DBR)) and a second (e.g., bottom) mirror structure (e.g., an n-type mirror structure, such as an n-type DBR (n-DBR)). Additional details are provided below.

In some implementations, the multi-junction VCSEL described herein enables improved WPE (e.g., as compared to a dilute nitride emitter with a single junction structure). Additionally, in some implementations, the multi-junction VCSEL described herein enables improved gain (e.g., as compared to a dilute nitride emitter with a single junction structure). In this way, the multi junction VCSEL structure enhances performance of a GaAs-based long-wavelength VCSEL.

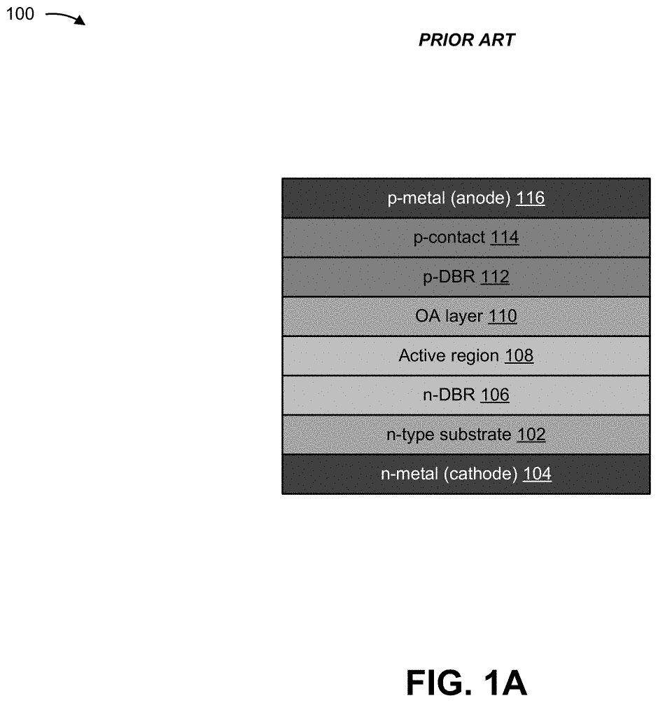

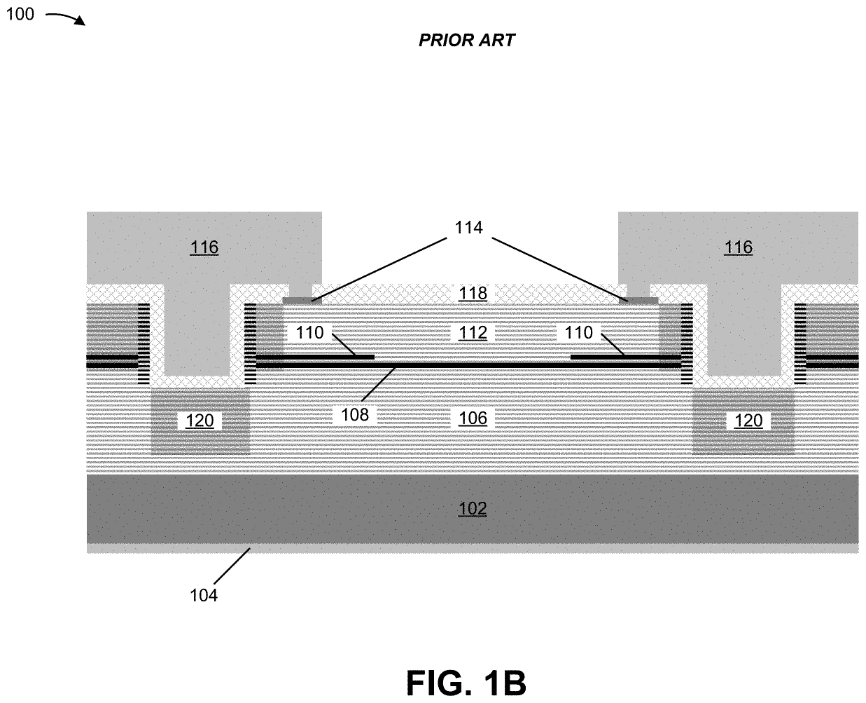

FIGS. 1A and 1B are diagrams associated with a conventional VCSEL array 100. FIG. 1A is a diagram illustrating various layers of the VCSEL array 100, while FIG. 1B is a diagram illustrating an example of a cross section of a particular VCSEL in the VCSEL array 100 with the layers shown in FIG. 1A. As shown in FIGS. 1A and 1B, the VCSEL array 100 includes an n-type substrate 102 with an n-type metal 104—serving as a cathode—on a bottom surface and an n-type DBR 106 on a top surface. As further shown, the VCSEL array 100 includes an active region 108 on the n-type DBR 106 and a p-type DBR 112 on the active region 108. As shown, the VCSEL array 100 further includes a p-type contact 114 on the p-type DBR 112, and a p-type metal 116—serving as an anode—on the p-type contact 114. As further shown, the VCSEL array 100 includes an optical aperture (OA) layer 110 comprising an aperture for providing optical and electrical confinement. As shown, the OA 110 is typically over the active region 108. Notably, as shown in FIG. 1B, the VCSEL array 100 further includes a dielectric layer 118 and an isolation implant 120.

The active region 108 of the VCSEL array 100 is a region comprising one or more quantum wells embedded in a semiconductor material. For example, the active region 108 may include GaAs quantum wells embedded in AlGaAs. As another example, the active region 108 may include InGaAs quantum wells embedded in GaAs. Notably, the quantum wells of the active region 108 are not formed from a dilute nitride material in the VCSEL array 100. Further, the VCSEL array 100 includes a single active region 108 and does not include a tunnel junction.

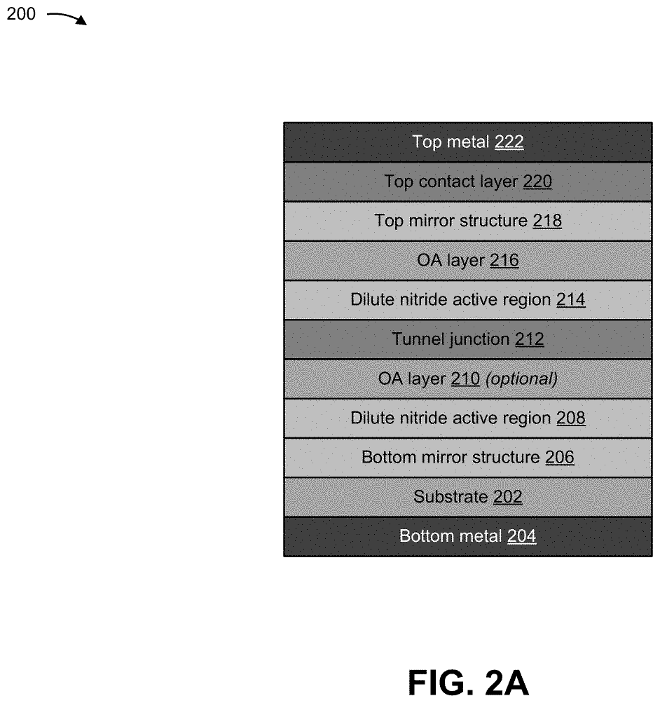

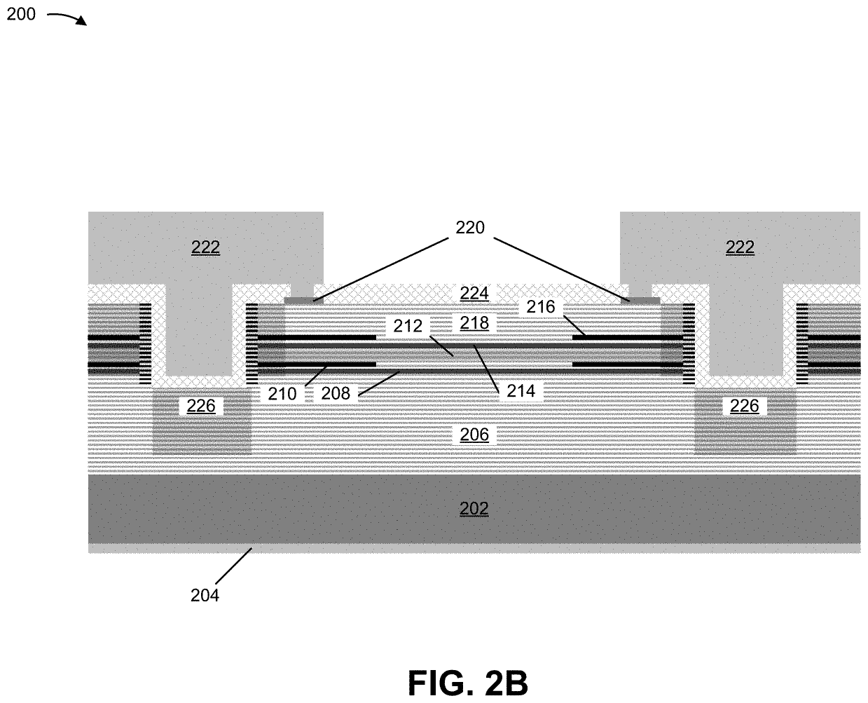

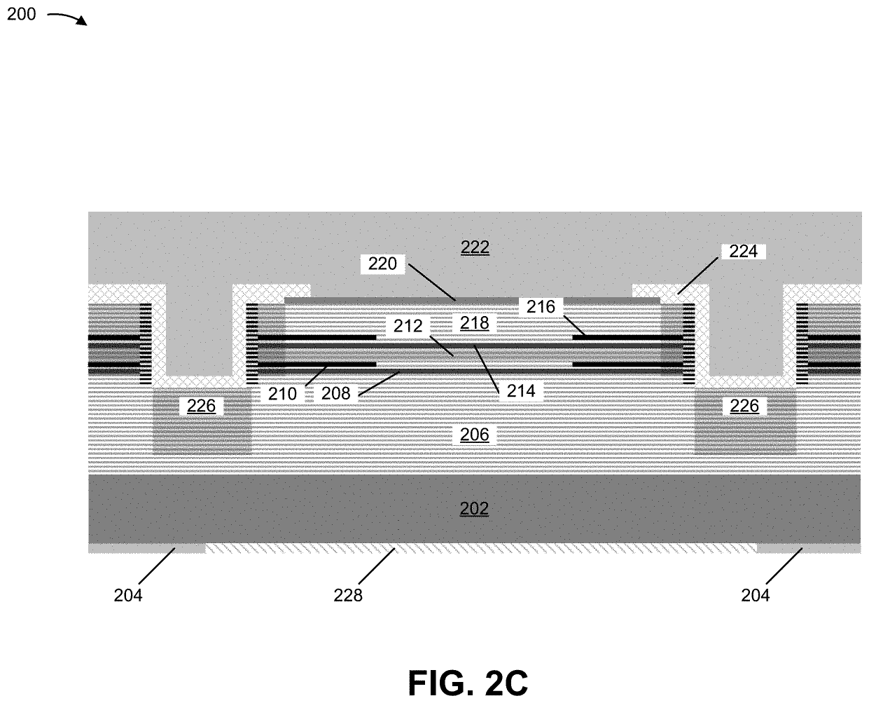

FIGS. 2A-2C are diagrams associated with a first example implementation of a VCSEL array 200 including multiple dilute nitride active regions connected in series by a tunnel junction. FIG. 2A is a diagram illustrating various layers of the VCSEL array 200. In some implementations, the VCSEL array 200 includes a single emitter. In some implementations, the VCSEL array 200 includes an array of emitters. In some implementations, the emitters of the VCSEL array 200 include one or more top-emitting emitters or one or more bottom-emitting emitters. As shown in FIG. 2A, the VCSEL array 200 may include a substrate 202, a bottom metal 204, a bottom mirror structure 206, a dilute nitride active region 208, an optional OA layer 210, a tunnel junction 212, a dilute nitride active region 214, an OA layer 216, a top mirror structure 218, a top contact layer 220, and a top metal 222.

Substrate 202 includes a supporting material upon which or within which one or more layers or features of the VCSEL array 200 are grown or fabricated. In some implementations, the substrate 202 comprises an n-type material. In some implementations, the substrate 202 comprises a semi-insulating type of material. In some implementations, the semi-insulating type of material may be used when the VCSEL array 200 includes one or more bottom-emitting emitters in order to reduce optical absorption from the substrate 202. In such an implementation, the VCSEL array 200 may include a contact buffer in or near the bottom mirror structure 206. In some implementations, the substrate 202 may be formed from a semiconductor material, such as gallium arsenide (GaAs), indium phosphide (InP), or another type of semiconductor material. In some implementations, a bottom contact (e.g., a bottom n-contact) of the VCSEL array 200 can be made from a backside of the substrate 202. In some implementations, the bottom contact of the VCSEL array 200 can be made from a front side of the VCSEL array 200. In some implementations, the front side contact can be achieved by, for example, etching a mesa step or trench to the substrate 202, or inserting a contact buffer in or near the bottom mirror structure 206.

Bottom metal 204 includes a metal layer on a bottom surface of the substrate 202 (e.g., at a backside of the VCSEL array 200). In some implementations, the bottom metal 204 is formed from an n-type material. In some implementations, the bottom metal 204 is a layer that makes electrical contact with the substrate 202. In some implementations, the bottom metal 204 serves as an anode for the VCSEL array 200. For example, in some implementations, the bottom metal 204 may serve as a common anode for a group of sub-arrays of a VCSEL array, where the VCSEL array 200 is one of the group of sub-arrays. In some implementations, the bottom metal 204 may include an annealed metallization layer, such as a gold-germanium-nickel (AuGeNi) layer, a palladium-germanium-gold (PdGeAu) layer, among other examples.

Bottom mirror structure 206 is a bottom reflector of an optical resonator of the VCSEL array 200. For example, the bottom mirror structure 206 may include a DBR, a dielectric mirror, or another type of mirror structure. In some implementations, the bottom mirror structure 206 is formed from an n-type material. In some implementations, the bottom mirror structure 206 is on a top surface of the substrate 202. In some implementations, the bottom mirror structure 206 may have a thickness in a range from approximately 3.5 microns (μm) to approximately 9 μm, such as 5 μm. In some implementations, the bottom mirror structure 206 includes a set of layers (e.g., aluminum gallium arsenide (AlGaAs) layers) grown using a metal-organic chemical vapor deposition (MOCVD) technique, a molecular beam epitaxy (MBE) technique, or another technique.

Dilute nitride active region 208 includes one or more layers where electrons and holes recombine to emit light and define the emission wavelength range of the VCSEL array 200, where one or more quantum wells of the dilute nitride active region 208 are formed from a dilute nitride material. The dilute nitride material may in some implementations comprise a composite semiconductor using a combination of InGaAlAsPSb with a ow percentage (e.g., less than approximately 5%) of Nitrogen added to a Group V site to remain lattice matched to a GaAs substrate without forming dislocations. The dilute nitride material from which the one or more quantum wells of the dilute nitride active region 208 are formed may include, for example, dilute nitride InGaAsN or InGaAsNSb. In some implementations, the dilute nitride active region 208 may include one or more cavity spacer layers. In some implementations, the one or more cavity spacer layers may enable epitaxial growth to have sufficient room for ramping compositions or temperature. In some implementations, the one or more cavity spacer layers may reduce strain between active regions of the dilute nitride active region 208. In some implementations, the one or more cavity spacer layers may mitigate thermal issues of laser operation. In some implementations, the one or more cavity spacer layers may include an oxidation layer. The optical thickness of the dilute nitride active region 208 (including cavity spacer layers), the tunnel junction 212, the dilute nitride active region 214 (including cavity spacer layers), the top mirror structure 218, and the bottom mirror structure 206 define the resonant cavity wavelength of the VCSEL array 200, which may be designed within an emission wavelength range of the dilute nitride active region 208 to enable lasing. In some implementations, the dilute nitride active region 208 may be formed on the bottom mirror structure 206. In some implementations, the dilute nitride active region 208 may have a thickness in a range from approximately 0.006 μm to approximately 0.5 μm, such as 0.15 μm or 0.30 μm. In some implementations, the dilute nitride active region 208 includes a set of layers grown using an MOCVD technique, an MBE technique, or another technique.

OA layer 210 is an optional layer for forming an aperture that provides optical and electrical confinement for the VCSELs of the VCSEL array 200. In some implementations, the OA layer 210 enhances carrier and mode confinement of the VCSEL array 200 and, therefore, can improve performance of the VCSEL array 200. In some implementations, the OA layer 210 is on, under, or in the dilute nitride active region 208. In some implementations, there may be one or more spacer layers or mirror layers (e.g., DBRs) between the OA layer 210 and the dilute nitride active region 208. In some implementations, the OA layer 210 is on a side of the dilute nitride active region 208 nearer to the bottom mirror structure 206 (i.e., on a substrate side of the dilute nitride active region 208). In some implementations, the OA layer 210 is on a side of the dilute nitride active region 208 nearer to the tunnel junction 212 (i.e., on a non-substrate side of the dilute nitride active region 208). In some implementations, the VCSEL array 200 may include one or more OA layers 210. For example, in some implementations, the VCSEL array 200 may include a first OA layer 210 on the side of the dilute nitride active region 208 nearer to the bottom mirror structure 206, and may include a second OA layer 210 on the side of the dilute nitride active region 208 nearer to the tunnel junction 212.

In some implementations, the OA layer 210 is an oxide layer formed as a result of oxidation of one or more epitaxial layers of the VCSEL array 200. For example, the OA layer 210 may be an aluminum oxide (Al₂O₃) layer formed as a result of oxidation of an epitaxial layer (e.g., an AlGaAs layer, an AlAs layer, and/or the like). In some implementations, the OA layer 210 may have a thickness in a range from approximately 0.007 μm to approximately 0.04 μm, such as 0.02 μm. In some implementations, oxidation trenches (not shown in FIG. 2A, and shown as filled in FIGS. 2B and 2C) etched around the VCSELs in the VCSEL array 200 may allow steam to access the epitaxial layer(s) from which the OA layer 210 is formed. In some implementations, the optical aperture has a circular shape. In some implementations, the optical aperture has a non-circular shape. In some implementations, a size (e.g., a diameter) of the optical aperture formed by the OA layer 210 is in a range from approximately 1 μm to approximately 300 μm, such as 5 μm or 8 μm. In some implementations, in addition to the one or more OA layers 210, the VCSEL array 200 may include one or more other types of structures or layers that provide current confinement, such as an implant passivation structure, a mesa isolation structure, a moat trench isolation structure, a buried tunnel junction, or the like. Additionally, or alternatively, such other types of structures or layers for providing current confinement may in some implementations be included in or integrated with one or more OA layers (e.g., one or more OA layers 210) of the VCSEL array 200.

Tunnel junction 212 comprises one or more layers to enables electrons and holes to tunnel through a junction barrier with low resistance and, additionally, to convert to one another. In some implementations, the tunnel junction 212 connects the dilute nitride active region 208 and the dilute nitride active region 214 in series. In some implementations, the tunnel junction 212 is formed with one or more layers of heavily doped p-type and n-type materials (typically referred to as p++and n++, respectively). For example, in some implementations, the tunnel junction is formed from one or more layers of a heavily doped n-type material on one or more layers of a heavily doped p-type material. In some implementations, the heavily doped p-type and n-type materials may have a doping concentration in a range from approximately 10¹⁹ per cubic centimeter (cm³) to approximately 10²⁰ per cm³. The tunnel junction 212 allows holes injected from below the tunnel junction 212 (through the dilute nitride active region 208) to be converted to electrons above the tunnel junction 212 (in the dilute nitride active region 214). In some implementations, the tunnel junction 212 may be sized such that the tunnel junction 212 fits within a null point of an electric field. Thus, in some implementations, the tunnel junction 212 may have a reduced thickness as compared to, for example, a tunnel junction layer of an edge-emitting laser. In some implementations, the tunnel junction 212 may have a total thickness in a range from approximately 0.01 μm to approximately 0.12 μm. In some implementations, the tunnel junction 212 is between the dilute nitride active region 208 and the dilute nitride active region 214.

Dilute nitride active region 214 includes one or more layers where electrons and holes recombine to emit light and define the emission wavelength range of the VCSEL array 200, where one or more quantum wells of the dilute nitride active region 214 are formed from a dilute nitride material. The dilute nitride material may in some implementations comprise a composite semiconductor using a combination of InGaAlAsPSO with a low percentage (e.g., less than approximately 5%) of Nitrogen added to a Group V site to remain lattice matched to a GaAs substrate without forming dislocations. The dilute nitride material from which the one or more quantum wells of the dilute nitride active region 214 are formed may include, for example, dilute nitride InGaAsN or InGaAsNSb. In some implementations, the dilute nitride active region 214 may include one or more cavity spacer layers. In some implementations, the one or more cavity spacer layers may enable epitaxial growth to have sufficient room for ramping compositions or temperature. In some implementations, the one or more cavity spacer layers may reduce strain between active regions of the dilute nitride active region 214. In some implementations, the one or more cavity spacer layers may mitigate thermal issues of laser operation. In some implementations, the one or more cavity spacer layers may include an oxidation layer. As noted above, the optical thickness of the dilute nitride active region 208 (including cavity spacer layers), the tunnel junction 212, the dilute nitride active region 214 (including cavity spacer layers), the top mirror structure 218, and the bottom mirror structure 206 define the resonant cavity wavelength of the VCSEL array 200, which may be designed within an emission wavelength range of the dilute nitride active region 214 to enable lasing. In some implementations, the dilute nitride active region 214 may be formed on the tunnel junction 212. In some implementations, the dilute nitride active region 214 may have a thickness in a range from approximately 0.006 μm to approximately 0.5 μm, such as 0.15 μm or 0.30 μm. In some implementations, the dilute nitride active region 214 includes a set of layers grown using an MOCVD technique, an MBE technique, or another technique.

In some implementations, the dilute nitride active region 208 and the dilute nitride active region 214 enable gain of the VCSEL array 200 (e.g., as compared to a VCSEL with a single dilute nitride active region) to be improved, thereby increasing power of the VCSEL array 200. Further, the multiple dilute nitride active regions enable the VCSEL array 200 to lase at lower threshold current at room temperature and remain lasing at higher temperatures, and lower carrier density in the multiple dilate nitride active regions improves reliability. Therefore, the multiple dilute nitride active regions of the VCSEL array 200 can provide increased power reliably over temperature.

In some implementations, the VCSEL array 200 may include more than two dilute nitride active regions and more than one tunnel junction. For example, in some implementations, the VCSEL array may include the (first) dilute nitride active region 208, the (second) dilute nitride active region 214, and a third dilute nitride active region (e.g., a dilute nitride active region with characteristics similar to those of the dilute nitride active region 208 or the dilute nitride active region 214). Here, the (first) tunnel junction 212 is between the dilute nitride active region 208 and the dilute nitride active region 214, and the VCSEL array 200 may include another tunnel junction (e.g., a tunnel junction with characteristic similar to those of the tunnel junction 212) between the dilute nitride active region 214 and the third dilute nitride active region. In some implementations, a higher number of dilute nitride active regions and tunnel junctions may increase power of the VCSEL array 200 and/or reliability of the VCSEL array 200 over temperature.

OA layer 216 is a layer for forming an aperture that provides optical and electrical confinement for the VCSELs of the VCSEL array 200. In some implementations, the OA layer 216 enhances carrier and mode confinement of the VCSEL array 200 and, therefore, can improve performance of the VCSEL array 200. In some implementations, the OA layer 216 is on, under, or in the dilute nitride active region 214. In some implementations, there may be one or more additional spacers or DBRs between the OA layer 216 and the dilute nitride active region 214. In some implementations, the one or more additional spacers or DBRs may reduce strain between the OA layer 216 and one or more other strained layers. In some implementations, the one or more additional spacers or DBRs may be included to accommodate a grade between the OA layer 216 and another layer of the VCSEL array 200. In some implementations, the OA layer 216 is on a side of the dilute nitride active region 214 nearer to the top mirror structure 218 (i.e., on a non-substrate side of the dilute nitride active region 214). In some implementations, the OA layer 216 is an oxide layer formed as a result of oxidation of one or more epitaxial layers of the VCSEL array 200. For example, the OA layer 216 may be an A₂O₃ layer formed as a result of oxidation of an epitaxial layer. In some implementations, the OA layer 216 may have a thickness in a range from approximately 0.007 μm to approximately 0.04 μm, such as 0.02 μm. In some implementations, oxidation trenches (not shown in FIG. 2A, and shown as filled in FIGS. 2B and 2C) etched around the VCSELs in the VCSEL array 200 may allow steam to access the epitaxial layer(s) from which the OA layer 216 is formed. In some implementations, the optical aperture has a circular shape. In some implementations, the optical aperture has a non-circular shape.

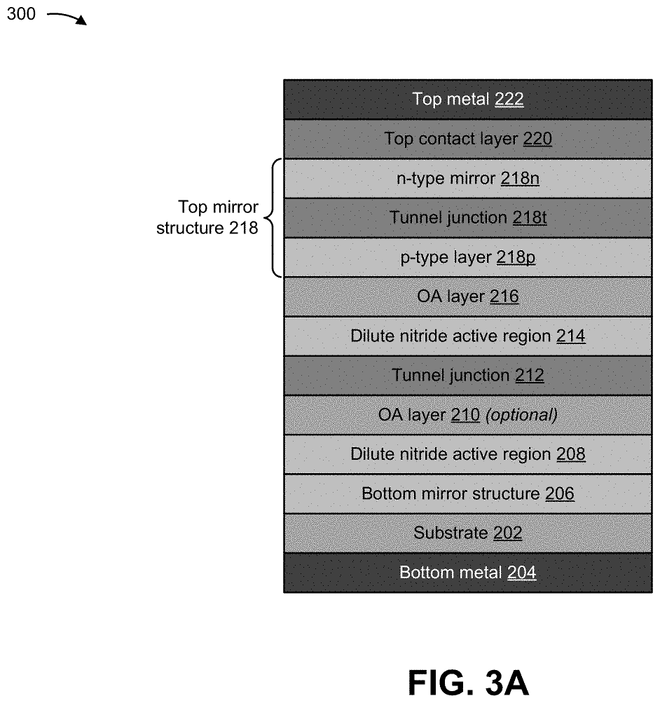

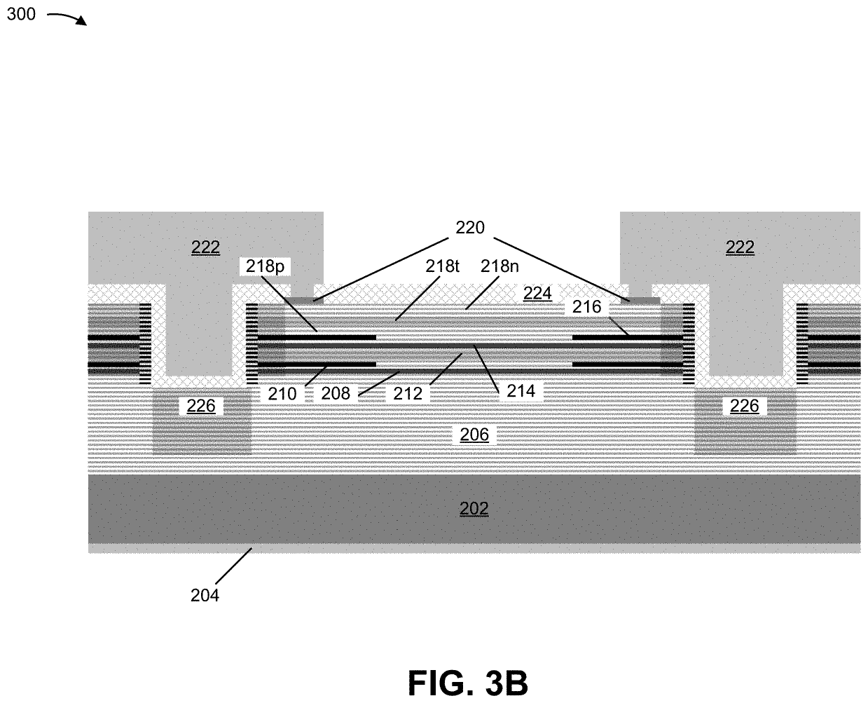

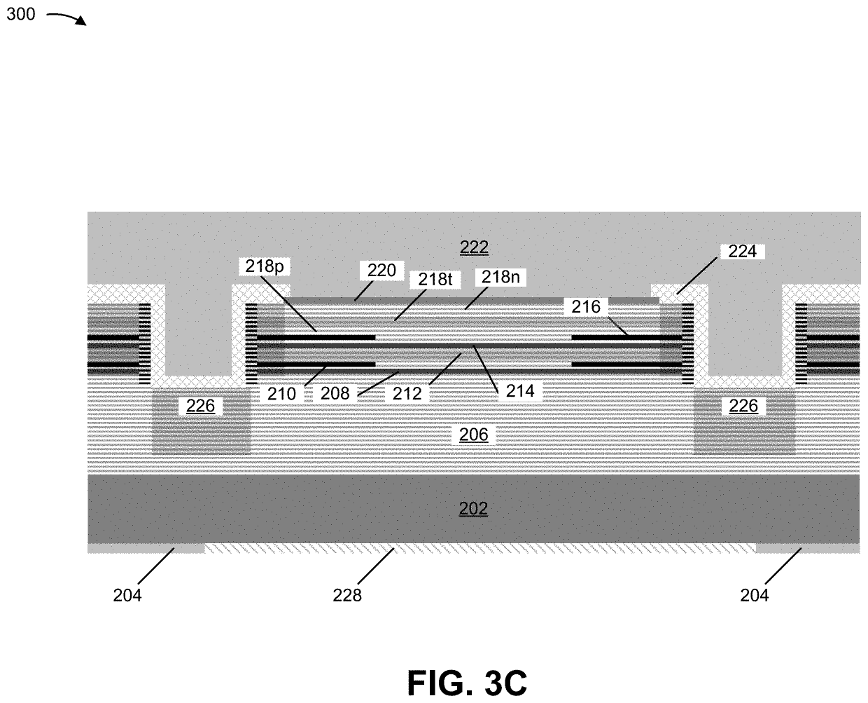

Top mirror structure 218 is a top reflector of the optical resonator of the VCSEL array 200. For example, the top mirror structure 218 may include a DBR, a dielectric mirror, and/or the like. In some implementations, the top mirror structure 218 is formed from a p-type material. Alternatively, in some implementations, at least a portion of the top mirror structure is formed from an n-type material. For example, in some implementations, the top mirror structure 218 may include a p-type layer (e.g., on the dilute nitride active region 214), a tunnel junction on the p-type layer, and an n-type mirror on the tunnel junction, an example of which is described in association with FIGS. 3A-3C. In some implementations, the top mirror structure 218 may have a thickness in a range from approximately 1 μm to approximately 6 μm, such as 3 μm. In some implementations, the top mirror structure 218 includes a set of layers (e.g., AlGaAs layers) grown using an MOCVD technique, an MBE technique, or another technique. In some implementations, the top mirror structure 218 is grown on or over the dilute nitride active region 214 In some implementations, a total thickness from a bottom surface of the bottom mirror structure 206 to a top surface of the top mirror structure 218 may be in a range from, for example, approximately 4.5 μm to approximately 26.4 μm, such as approximately 8.6 μm. In some implementations, a thickness of one or more of the layers of the VCSEL array 200 may be selected in order to provide a structure that achieves high reflectively (e.g., greater than approximately 99% reflectivity). In some implementations, a smaller total thickness may be facilitate growth time reduction of the VCSEL array 200 or stress reduction within the VCSEL array 200.

The top contact layer 220 is a top contact layer of the VCSEL array 200 that makes electrical contact with the top mirror structure 218 through which current may flow. In some implementations, the top contact layer 220 includes an annealed metallization layer. For example, the top contact layer 220 may include a chromium-gold (Cr—Au) layer, a gold-zinc (Au—Zn), a titanium-platinum-gold (TiPtAu) layer, a gold-germanium-nickel (AuGeNi) layer, a palladium-germanium-gold (PdGeAu) layer, or the like. In some implementations, the top contact layer 220 has a thickness in a range from approximately 0.03 μm to approximately 0.3 μm, such as 0.2 μm. In some implementations, the top contact layer 220 has a ring shape, a slotted ring shape, a tooth wheel shape, or another type of circular or non-circular shape (e.g., depending on a design of the VCSELs in the VCSEL array 200).

The top metal 222 is a top metal layer at a front side of the VCSEL array 200. In some implementations, the top metal 222 is formed from a p-type material. Alternatively, in some implementations, the top metal 222 is formed from an n-type material. In some implementations, the top metal 222 may be a layer that makes electrical contact with the top contact layer 220. In some implementations, the top metal 222 may serve as a cathode for the VCSEL array 200. For example, in some implementations, the top metal 222 may serve as an isolated cathode for a particular sub-array of a VCSEL array including a group of sub-arrays, where the VCSEL array 200 is one of the group of sub-arrays.

FIG. 2B is a diagram illustrating an example of a cross section of a top-emitting VCSEL in the VCSEL array 200 with the layers shown in FIG. 2A. As shown in FIG. 2B, the top metal 222 is insulated from sidewalls of the trenches by a dielectric layer 224, which may be, for example, silicon nitride (SiN), silicon dioxide (SiO₂), a polymer dielectric, or another type of insulating material. Additionally, as shown in FIG. 2B, the VCSEL may have an isolation implant 226 to prevent free carriers from reaching edges of the trenches and/or to isolate adjacent VCSELs in the VCSEL array 200 from one another (e.g., if the trenches do not fully enclose the VCSELs of the VCSEL array 200).

FIG. 2C is a diagram illustrating an example of a cross section of a bottom-emitting VCSEL in the VCSEL array 200 with the layers shown in FIG. 2A. The structure of the bottom-emitting VCSEL may be similar to that of the top-emitting VCSEL shown in FIG. 2B with some exceptions. For example, as illustrated in FIG. 2C, in the case of the bottom-emitting VCSEL, an opening is present in the bottom metal 204 to permit emission of light out of the substrate 202. In some implementations, as shown in FIG. 2C, an anti-reflective (AR) coating 228 may be formed in the opening in the bottom metal 204. As further shown in FIG. 2C, in the bottom-emitting VCSEL, the top metal 222 covers the top surface of the VCSEL emitter over the top contact layer 220. Other examples of structural differences between the top-emitting VCSEL and the bottom-emitting VCSEL may include the contact layer 220 and the top metal 222 being differently formed in the bottom-emitting VCSEL, the positions of the top mirror structure 218 and the bottom mirror structure 206 being reversed (not illustrated in FIG. 2C) in the bottom-emitting VCSEL, the substrate 202 being thinned in the bottom-emitting VCSEL (not illustrated in FIG. 2C), or one or more OA layers (e.g., one or more OA layers 210 and/or one or more OA layers 216) being differently formed, among other examples.

Notably, while the multi-junction structure illustrated in FIGS. 2A-2C shows the VCSEL array 200 as including two dilute nitride active regions connected by a single tunnel junction, the design of the VCSEL array 200 can be extended to a dilute nitride VCSEL array having a higher number of active regions connected by tunnel junctions in a similar manner as that described in association with FIGS. 2A-2C. For example, the VCSEL array 200 may include a second tunnel junction (e.g., similar to the tunnel junction 212) over the dilute nitride active region 214, and a third dilute nitride active region (e.g., similar to the dilute nitride active region 208 or the dilute nitride active region 214) over the second tunnel junction (e.g., such that the third dilute nitride active region is between the second tunnel junction and the top mirror structure 218).

The number, arrangement, thicknesses, order, symmetry, or the like, of layers shown in FIGS. 2A-2C are provided as examples. In practice, VCSEL array 200 may include additional layers, fewer layers, different layers, differently constructed layers, or differently arranged layers than those shown in FIGS. 2A-2C. For example, the VCSEL array 200 may include one or more cladding layers, one or more spacer layers (e.g., near the bottom mirror structure 206, the OA layer 210, the tunnel junction 212, and/or the OA layer 216), one or more additional mirror structures, or the like, not shown in FIGS. 2A-2C. Additionally, or alternatively, a set of layers (e.g., one or more layers) of VCSEL array 200 may perform one or more functions described as being performed by another set of layers of VCSEL array 200, and any layer may comprise more than one layer.

P-type carriers have more optical absorption than n-type carriers, and become more severe at longer wavelengths. Therefore, performance of a VCSEL array can be improved by replacing at least a portion of a p-type mirror structure with an n-type mirror structure (e.g., to reduce optical absorption and enhance power and WPE of the VCSEL array). Therefore, in some implementations, a VCSEL array may include a tunnel junction that enables an n-type mirror structure to be used in place of at least some portion of a p-type mirror structure.

FIGS. 3A-3C are diagrams associated with an example implementation of a VCSEL array 300 including dilute nitride active regions 208 and 214 connected in series by tunnel junction 212, where an n-type mirror is used in place of at least a portion of a p-type mirror within the top mirror structure 218. FIG. 3A is a diagram illustrating various layers of the VCSEL array 300. FIG. 3B is a diagram illustrating an example of a cross section of a top-emitting VCSEL in the VCSEL array 300 with the layers shown in FIG. 3A, and FIG. 3C is a diagram illustrating an example of a cross section of a bottom-emitting VCSEL in the VCSEL array 300 with the layers shown in FIG. 3A.

As illustrated by comparing FIGS. 2A-2C and FIGS. 3A-3C, the structure of the VCSEL array 300 is similar to that of the VCSEL array 200 except that the top mirror structure 218 in the VCSEL array 300 includes a p-type layer 218p, a tunnel junction 218t on the p-type layer 218p, and an n-type mirror 218n on the tunnel junction 218t (e.g., rather than including only a p-type mirror).

P-type layer 218p is a mirror section of the top mirror structure 218. In some implementations, the p-type layer 218p is a portion of the top reflector of the optical resonator and is formed from a p-type material. In some implementations, as shown in FIG. 3A, the p-type layer 218p may be between the dilute nitride active region 214 and the tunnel junction 218t. In some implementations, the p-type layer 218p may include a DBR, a dielectric mirror, or another type of mirror structure. In some implementations, the p-type layer 218p is a thin p-type DBR (p-DBR) (e.g., a p-DBR having fewer than six layer pairs) that forms a portion of the bottom reflector of the optical resonator. In some implementations, the p-type layer 218p is a p-type spacer layer (e.g., one layer of a single material, such as GaAs or AlGaAs) that supports electron injection in the n-type mirror 218n but does not serve as a portion of the top reflector of the optical resonator.

Tunnel junction 218t comprises one or more layers to reverse a carrier type within the top mirror structure 218. For example, the tunnel junction 218t may include one or more layers that convert holes from the p-type layer 218p to electrons in the n-type mirror 218n. In some implementations, the tunnel junction 218t is formed with one or more layers of highly doped n-type and p-type materials (e.g., similar to the tunnel junction 212 described above). The tunnel junction 218t allows holes injected from below the tunnel junction 218t (through the p-type layer 218p) to be converted to electrons above the tunnel junction 218t (in the n-type mirror 218n). In some implementations, the tunnel junction 218t may have a total thickness in a range from approximately 0.01 μm to approximately 0.12 μm. In some implementations, the tunnel junction 218t is within the top mirror structure 218, which permits a low resistance transition from the p-type layer 218p to the n-type mirror 218n.

In some implementations, the tunnel junction 218t may be formed at any location in the top mirror structure 218. For example, the tunnel junction 218t may be formed at a bottom of the top mirror structure 218 (e.g., at a location below which there are no layer pairs). Notably, there is a trade-off in the voltage drop through the p-type layer 218p (e.g., one or more p-DBR pairs) versus the voltage drop through the tunnel junction 218t. As the tunnel junction 218t is placed closer to the aperture formed by the OA layer 216 (i.e., lower in the top mirror structure 218), current is laterally confined to a narrower region and, therefore, the current density is higher, as is voltage drop across the tunnel junction 218t. However, in such a case, there are fewer (higher resistance) p-DBR pairs through which current must pass. The p-DBR pairs generally have higher lateral resistance than n-DBR pairs and often have a higher vertical resistance. As the location of the tunnel junction 218t shifts away from the dilute nitride active region 214, more p-DBR pairs are needed in the p-type layer 218p above the tunnel junction 218t, but the current density and corresponding voltage drop across the tunnel junction 218t will be lower. Thus, the placement of the tunnel junction 218t within the top mirror structure 218 can be selected depending on the resistance of the tunnel junction 218t. For sufficiently low tunnel junction resistance (e.g., less than approximately 2×10⁻⁵ ohm-centimeters squared (cm²)), placement of the tunnel junction 218t close to the aperture formed by the OA layer 216 may be advantageous to improve electrical to optical power conversion efficiency.

In some implementations, by forming the top mirror structure 218 to include the p-type layer 218p, the tunnel junction 218t, and the n-type mirror 218n, the top contact layer 220 of the VCSEL array 300, the thickness of the layer with p-carriers in the VCSEL array 300 are reduced, thereby enabling reduced optical absorption and enhancing power and WPE of the VCSEL array 300.

Notably, while the multi-junction structure illustrated in FIGS. 3A-3C shows the VCSEL array 300 as including two dilute nitride active regions connected by a single tunnel junction, the design of the VCSEL array 300 can be extended to a dilute nitride VCSEL array having a higher number of active regions connected by tunnel junctions in a similar manner as that described above in association with FIGS. 2A-2C.

The number, arrangement, thicknesses, order, symmetry, or the like, of layers shown in FIGS. 3A-3C are provided as examples. In practice, VCSEL array 300 may include additional layers, fewer layers, different layers, differently constructed layers, or differently arranged layers than those shown in FIGS. 3A-3C. For example, the VCSEL array 300 may include one or more cladding layers, one or more spacer layers (e.g., near the bottom mirror structure 306, the OA layer 310, the tunnel junction 313, and/or the OA layer 316), one or more additional mirror structures, or the like, not shown in FIGS. 3A-3C. Additionally, or alternatively, a set of layers (e.g., one or more layers) of VCSEL array 300 may perform one or more functions described as being performed by another set of layers of VCSEL array 300 and any layer may comprise more than one layer.

In some implementations, a VCSEL array 200/300 may be manufactured using a series of procedures. For example, one or more layers of VCSEL array 200/300 may be created using one or more growth procedures, one or more deposition procedures, one or more etching procedures, one or more oxidation procedures, one or more implantation procedures, and/or one or more metallization procedures, among other examples.

A particular example of a process for fabricating a VCSEL array 200/300 is as follows. First, crystalline layers (e.g., GaAs/AlGaAs layers) may be grown (e.g., laterally uniform) upon a substrate 202 (e.g., an n-type GaAs substrate) to form the bottom mirror structure 206, the dilute nitride active region 208, the tunnel junction 212, the top mirror structure 218 (e.g., including the p-type layer 218p, the tunnel junction 218t, and the n-type mirror 218n in the case of VCSEL array 300). Next, the top contact layer 220 may be deposited. This step may also be performed after oxidation of the OA layer 210 and the OA layer 216 as described below. Next, trenches may be etched to permit lateral oxidation (either partially or fully surrounding emitters). Next, the OA layer 210 and the OA layer 216 (e.g., higher Al content layer(s)) may be oxidized to form the aperture(s). Next, emitters belonging to different cathodes can be isolated by ion implantation through formation of isolation implant 226 (e.g., when emitters are not isolated by etching in the previous step, or when additional isolation is desired). Next, interconnect and pad metallization (e.g., the top metal 222) is deposited as needed. Next, the substrate 202 may be thinned (e.g., as required for wafer dicing). Next, the bottom metal 204 may be deposited on the backside of the thinned substrate 202. Finally, the wafer may be diced. Notably, there may be one or more additional steps performed at various points between the above-described steps, such as surface passivation, strain compensation, heat treatment, photolithography, cleaning, patterning, or the like. Further, some of the above-described steps may require patterning of the wafer to be performed (e.g., in order to etch, metalize, or isolate only specific regions across each VCSEL array 200/300 or within each emitter).

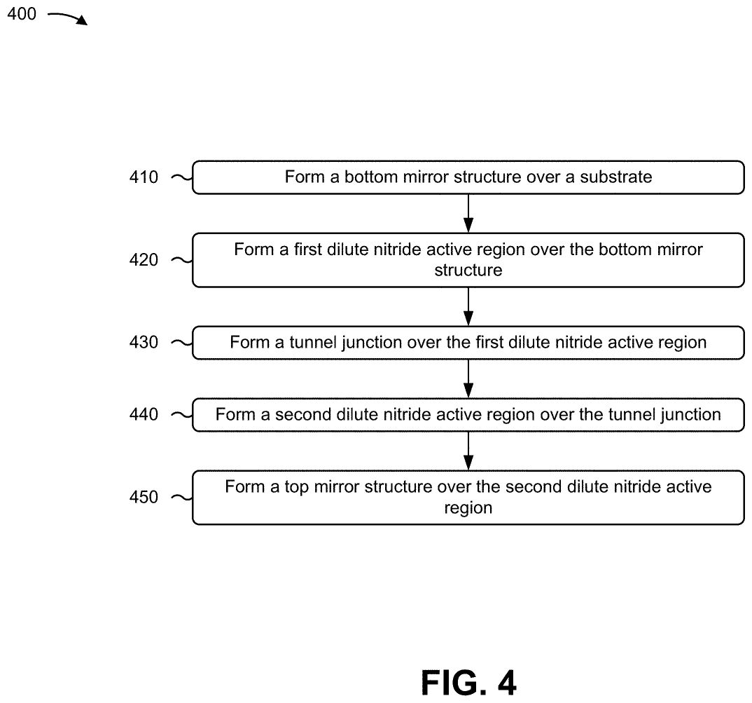

FIG. 4 is a flowchart of an example process 400 relating to manufacturing a VCSEL including multiple dilute nitride active regions connected in series by one or more tunnel junctions.

As shown in FIG. 4, process 400 may include forming a bottom mirror structure over a substrate (block 410). For example, a bottom mirror structure (e.g., the bottom mirror structure 106) may be formed over a substrate (e.g., a substrate 202), as described above.

As further shown in FIG. 4, process 400 may include forming a first dilute nitride active region over the bottom mirror structure (block 420). For example, a first dilute nitride active region (e.g., the dilute nitride active region 208) may be formed over the bottom mirror structure, as described above.

As further shown in FIG. 4, process 400 may include forming a tunnel junction over the first dilute nitride active region (block 430). For example, a tunnel junction (e.g., the tunnel junction 212) may be formed over the first dilute nitride active region, as described above.

As further shown in FIG. 4, process 400 may include forming a second dilute nitride active region over the tunnel junction (block 440). For example, a second dilute nitride active region (e.g., the dilute nitride active region 214) may be formed over the tunnel junction, as described above.

As further shown in FIG. 4, process 400 may include forming a top mirror structure over the second dilute nitride active region (block 450). For example, a top mirror structure (e.g., the top mirror structure 218) may be formed over the second dilute nitride active region, as described above.

Process 400 may include additional implementations, such as any single implementation or any combination of implementations described below and/or in connection with one or more other processes described elsewhere herein.

In a first implementation, the first dilute nitride active region and the second dilute nitride active region are connected in series by the tunnel junction.

In a second implementation, alone or in combination with the first implementation, the tunnel junction is a first tunnel junction, and process 400 includes forming a second tunnel junction (e.g., a tunnel junction similar to tunnel junction 212) over the second dilute nitride active region, and forming a third dilute nitride active region (e.g., a dilute nitride active region similar to the dilute nitride active region 208 or the dilute nitride active region 214) over the second tunnel junction, wherein the third dilute nitride active region is between the second tunnel junction and the top mirror structure.

In a third implementation, alone or in combination with one or more of the first and second implementations, process 400 includes forming one or more OA layers (e.g., one or more OA layers 210) on, under, or in the first dilute nitride active region.

In a fourth implementation, in combination with the third implementation, an OA layer of the one or more OA layers is on a side of the first dilute nitride active region nearer to the bottom mirror structure.

In a fifth implementation, alone or in combination with one or more of the third and fourth implementations, an OA layer of the one or more OA layers is on a side of the first dilute nitride active region nearer to the tunnel junction.

In a sixth implementation, alone or in combination with one or more of the first through fifth implementations, the tunnel junction is a first tunnel junction, and the top mirror structure comprises a p-type layer (e.g., the p-type layer 218p) over the second dilute nitride active region, a second tunnel junction (e.g., the tunnel junction 218t) over the p-type layer, and an n-type mirror (e.g., the n-type mirror 218n) over the second tunnel junction.

In a seventh implementation, in combination with the sixth implementation, the placement of the second tunnel junction within the top mirror structure is based on a resistance of the second tunnel junction.

In an eighth implementation, alone or in combination with one or more of the sixth and seventh implementations, the p-type layer, the second tunnel junction, and the n-type mirror enable reduced optical absorption or enhanced power and wall plug efficiency of the VCSEL.

In a ninth implementation, alone or in combination with one or more of the first through seventh implementations, a VCSEL array (e.g., the VCSEL array 200, the VCSEL array 300) has a lasing wavelength in a range from approximately 1200 nm to approximately 1600 nm.

In an tenth implementation, alone or in combination with one or more of the first through ninth implementations, the first dilute nitride active region or the second dilute nitride active region comprises InGaAsN or InGaAsNSb.

In an eleventh implementation, alone or in combination with one or more of the first through tenth implementations, process 400 includes forming one or more OA layers (e.g., one or more OA layers 216) on, under, or in the second dilute nitride active region.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise form disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “over,” “under,” “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a substrate;
a bottom mirror structure over the substrate;
a first dilute nitride active region over the bottom mirror structure;
a tunnel junction over the first dilute nitride active region;
a second dilute nitride active region over the tunnel junction; and
a top mirror structure over the second dilute nitride active region.

2. The VCSEL of claim 1, wherein the first dilute nitride active region and the second dilute nitride active region are connected in series by the tunnel junction.

3. The VCSEL of claim 1, wherein the tunnel junction is a first tunnel junction, and the VCSEL further comprises:
a second tunnel junction over the second dilute nitride active region, and
a third dilute nitride active region over the second tunnel junction,
wherein the third dilute nitride active region is between the second tunnel junction and the top mirror structure.

4. The VCSEL of claim 1, further comprising one or more optical aperture (OA) layers on, under, or in the first dilute nitride active region.

5. The VCSEL of claim 4, wherein an OA layer of the one or more OA layers is on a side of the first dilute nitride active region nearer to the bottom mirror structure.

6. The VCSEL of claim 4, wherein an OA layer of the one or more OA layers is on a side of the first dilute nitride active region nearer to the tunnel junction.

7. The VCSEL of claim 1, wherein the tunnel junction is a first tunnel junction, and the top mirror structure comprises a p-type layer over the second dilute nitride active region, a second tunnel junction over the p-type layer, and an n-type mirror over the second tunnel junction.

8. The VCSEL of claim 7, wherein the placement of the second tunnel junction within the top mirror structure is based on a resistance of the second tunnel junction.

9. The VCSEL of claim 7, wherein the p-type layer, the second tunnel junction, and the n-type mirror enable reduced optical absorption or enhanced power and wall plug efficiency of the VCSEL.

10. The VCSEL of claim 1, wherein the VCSEL has a lasing wavelength in a range from approximately 1200 nanometers (nm) to approximately 1600 nm.

11. The VCSEL of claim 1, wherein the first dilute nitride active region or the second dilute nitride active region comprise indium gallium arsenide nitride (InGaAsN) or InGaAsN antimony (InGaAsNSb).

12. The VCSEL of claim 1, further comprising one or more optical aperture (OA) layers on, under, or in the second dilute nitride active region.

13. A vertical-cavity surface-emitting laser (VCSEL), comprising:
a substrate;
a bottom mirror structure over the substrate;
a plurality of dilute nitride active regions over the bottom mirror structure;
a set of tunnel junctions over the bottom mirror structure,
wherein a tunnel junction of the set of tunnel junctions is between a pair of dilute nitride active regions of the plurality of dilute nitride active regions; and
a top mirror structure over the plurality of dilute nitride active regions and the set of tunnel junctions.

14. The VCSEL of claim 13, wherein the pair of dilute nitride active regions is connected in series by the tunnel junction.

15. The VCSEL of claim 13, further comprising at least one or more optical aperture (OA) layers on, under, or in a dilute nitride active region of the plurality of dilute nitride active regions.

16. The VCSEL of claim 13, wherein the top mirror structure comprises a p-type layer over a topmost dilute nitride active region of the plurality of dilute nitride active regions, another tunnel junction over the p-type layer, and an n-type mirror over the other tunnel junction.

17. An emitter, comprising:
a first dilute nitride active region;
a second dilute nitride active region; and
a tunnel junction between the first dilute nitride active region and the second dilute nitride active region,
wherein the first dilute nitride active region and the second dilute nitride active region are connected in series by the tunnel junction.

18. The emitter of claim 17, wherein the tunnel junction is a first tunnel junction, and the emitter further comprises:
a third dilute nitride active region, and
a second tunnel junction between the second dilute nitride active region and the third dilute nitride active region,
wherein the second dilute nitride active region and the third dilute nitride active region are connected in series by the second tunnel junction.

19. The emitter of claim 17, further comprising one or more optical aperture (OA) layers on, under, or in at least one of the first dilute nitride active region or the second dilute nitride active region.

20. The emitter of claim 17, wherein the tunnel junction is a first tunnel junction, and the emitter further comprises a p-type layer over the second dilute nitride active region, a second tunnel junction over the p-type layer, and an n-type mirror over the second tunnel junction.
